(19) United States
(12) Patent Application Publication
(10) Pub. No.: US 2019/0089126 A1
(43) Pub. Date: Mar. 21, 2019

(54) TRANSISTOR OUTLINE (TO) CAN PACKAGE WITH INTEGRATED THERMOELECTRIC COOLER

(71) Applicant: Phononic, Inc., Durham, NC (US)

(72) Inventors: Alex R. Guichard, Apex, NC (US); Michael J. Bruno, Holly Springs, NC (US); Jeffrey Alan Morrow, Redmond, WA (US); Abhishek Yadav, Cary, NC (US)

(21) Appl. No.: 15/710,101

(22) Filed: Sep. 20, 2017

(51) Int. Cl. H01S 5/024; H01S 5/022; H01L 35/32; H01L 35/34; H01L 35/08

(52) U.S. Cl. CPC H01S 5/02415; H01S 5/02212; H01L 35/08; H01L 35/34; H01L 35/325

(57) ABSTRACT

Embodiments of a Transistor Outline (TO) can package having an integrated Thermoelectric Cooler (TEC) and methods of manufacturing a TO can package having an integrated TEC are disclosed. In some embodiments, a TO can package comprises a TO header and a TEC on a surface of the TO header. The TEC comprises an insulation layer on a surface of the TO header, where the insulation layer has a thickness that is less than 100 micrometers and comprises one or more thermally and electrically conductive materials. The TEC further comprises a plurality of thermoelectric devices on a surface of the insulation layer opposite the TO header. The thin insulation layer, as opposed to a relatively thick bottom header of a stand-alone TEC, enables taller N-type and P-type legs for the thermoelectric devices, and thus a higher Coefficient of Performance (COP), within a given height for the TEC.

### FIELD OF THE DISCLOSURE

The present disclosure relates to a Transistor Outline (TO) can package having an integrated Thermoelectric Cooler (TEC).

### BACKGROUND

Laser diodes are commonly used in a wide variety of applications such as, for example, fiber optic communications, optical disk reading and writing, laser printing, laser scanning, and the like. A laser diode is oftentimes packaged in a Transistor Outline (TO) can package. One example of a TO can package 10 including a laser diode 12 is illustrated in FIG. 1. As shown, the TO can package 10 includes a TO header 14 and a TO cap 16. In general, the TO header 14 provides structural support for a laser diode assembly that is within the TO cap 16. In this example, the laser diode assembly includes the laser diode 12, a heat sink 18 to which the laser diode 12 is mounted, and a photodiode 20 that monitors a reverse laser beam emitted from the laser diode 12. Power is provided to the laser diode 12 via pins 22 and 24. The output of the photodiode 20 can be monitored via a pin 26. The TO cap 16 is a protective cap and includes a window 28 through which a forward laser beam is emitted from the laser diode 12.

One issue with laser diodes is that their operation fluctuates with temperature. Precise temperature control is desirable to maintain output power and wavelength as well as to protect against over temperature conditions that can damage or prematurely age the laser diodes.

One solution to this issue is to use external Thermoelectric Coolers (TECs) and an associated temperature controller to provide precise temperature control for a laser diode. The TECs are external to the TO can package. In this regard, FIGS. 2 and 3 illustrate one example of a TEC 30. The TEC 30 includes a bottom ceramic, or thermally conductive substrate, 32, a bottom metallization layer 34, a number of alternating N-type and P-type legs 36 and 38, a top metallization layer 40, and a top header 42. The bottom and top headers 32 and 42 are formed of an electrically insulating, thermally conductive material (e.g., a ceramic material). The top and bottom metallization layers 34 and 40 connect the alternating N-type and P-type legs 36 and 38 to provide multiple thermoelectric devices connected in series. Each thermoelectric device consists of one N-type leg and one P-type leg, as will be appreciated by one of ordinary skill in the art.

FIG. 4 illustrates one known mounting scheme that utilizes TECs to provide temperature control for a laser diode. FIG. 4 is substantially reproduced from FIG. 4 of Lawrence A. Johnson, “Controlling Temperatures of Diode Lasers Thermoelectrically,” ILX Lightwave Corporation, 2003. The laser diode is packaged in a TO can package. The TECs are external to the TO can package.

However, there is a need for further improvement in laser diode cooling.

### SUMMARY

Embodiments of a Transistor Outline (TO) can package having an integrated Thermoelectric Cooler (TEC) and methods of manufacturing a TO can package having an integrated TEC are disclosed. In some embodiments, a TO can package comprises a TO header and a TEC on a surface of the TO header. The TEC comprises an insulation layer on a surface of the TO header, where the insulation layer has a thickness that is less than 100 micrometers (μm) and comprises one or more thermally and electrically conductive materials. The TEC further comprises a plurality of thermoelectric devices on a surface of the insulation layer opposite the TO header. The thin insulation layer, as opposed to a relatively thick bottom header of a stand-alone TEC, enables taller N-type and P-type legs for the thermoelectric devices, and thus a higher Coefficient of Performance (COP), within a given height for the TEC.

In some embodiments, the thickness of the insulation layer is less than 75 μm. In some other embodiments, the thickness of the insulation layer is less than 50 μm. In some other embodiments, the thickness of the insulation layer is less than 25 μm. In some other embodiments, the thickness of the insulation layer is less than 10 μm. In some other embodiments, the thickness of the insulation layer is less than 5 μm.

In some embodiments, the plurality of thermoelectric devices are arranged into a single layer of thermoelectric devices. In some other embodiments, the plurality of thermoelectric devices are arranged into multiple cascaded layers of thermoelectric devices.

In some embodiments, the TO can package further comprises a semiconductor device assembly on a surface of the TEC opposite the TO header. In some embodiments, the semiconductor device assembly comprises a laser diode assembly.

In some embodiments, a method of manufacturing a TO can package comprises forming a TEC on a surface of a TO header of the TO can package such that the TEC comprises: an insulation layer on a surface of the TO header, where the insulation layer has a thickness that is less than 100 μm and comprises one or more thermally and electrically conductive materials; and a plurality of thermoelectric devices a surface of the insulation layer opposite the TO header.

In some embodiments, the thickness of the insulation layer is less than 75 μm. In some other embodiments, the thickness of the insulation layer is less than 50 μm. In some other embodiments, the thickness of the insulation layer is less than 25 μm. In some other embodiments, the thickness of the insulation layer is less than 10 μm. In some other embodiments, the thickness of the insulation layer is less than 5 μm.

In some embodiments, forming the TEC comprises forming the insulation layer on the surface of the TO header. In some embodiments, forming the insulation layer comprises depositing the insulation layer on the surface of the TO header.

In some embodiments, forming the TEC further comprises forming a first metallization layer of the TEC on the surface of the insulation layer opposite the TO header. In some embodiments, forming the TEC further comprises attaching a structure to the first metallization layer to thereby form the TEC, where the structure comprises a plurality of thermoelectric device legs and a second metallization layer. Further, attaching the structure to the first metallization layer comprises attaching the plurality of thermoelectric device legs to the first metallization layer such that, together, the first metallization layer, the plurality of thermoelectric device legs, and the second metallization layer form a plurality of series-connected thermoelectric devices.

In some embodiments, the plurality of thermoelectric devices are arranged into a single layer of thermoelectric devices. In some other embodiments, the plurality of thermoelectric devices are arranged into multiple cascaded layers of thermoelectric devices.

In some embodiments, the method further comprises attaching a semiconductor device assembly to a surface of the TEC opposite the TO header. In some embodiments, the semiconductor device assembly comprises a laser diode assembly.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates one example of a laser diode Transistor Outline (TO) can package;

FIGS. 2 and 3 illustrate one example of a Thermoelectric Cooler (TEC);

FIG. 4 illustrates one known mounting scheme that utilizes TECs to provide temperature control for a laser diode;

FIG. 5 illustrates one example of a TO can package having an integrated TEC;

FIG. 6 illustrates one example of a TO can package having an integrated TEC in accordance with some embodiments of the present disclosure; and

FIGS. 7A through 7E illustrate a process for manufacturing a TO can package according to some embodiments of the present disclosure.

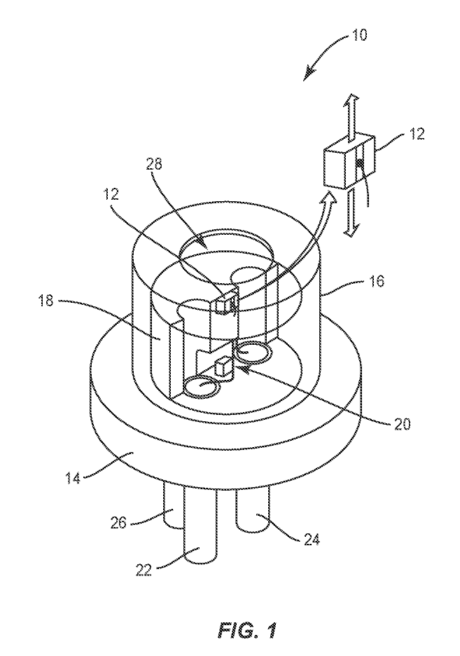

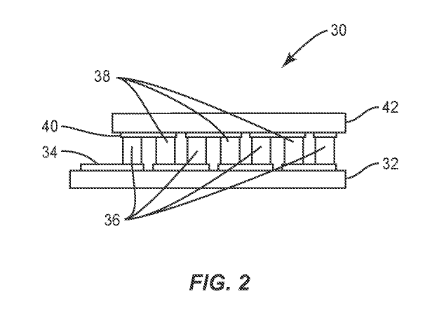

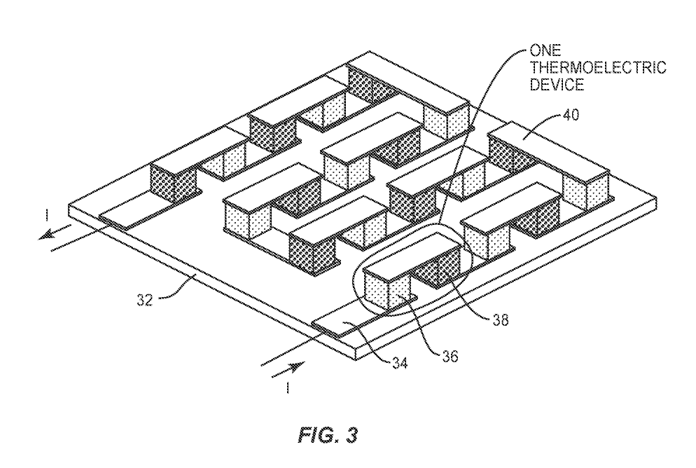

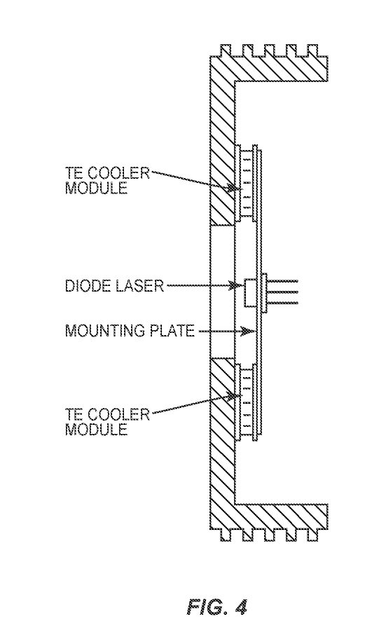

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

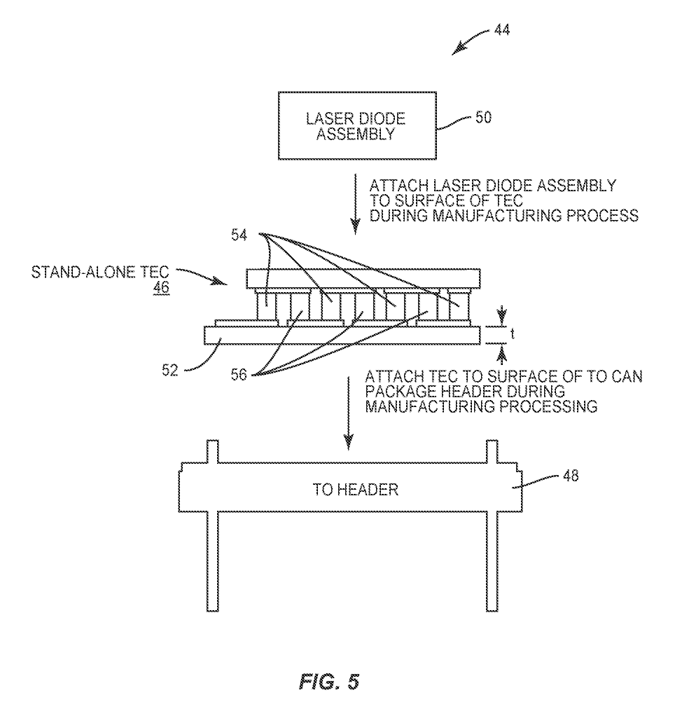

One issue with conventional schemes for cooling laser diodes using Thermoelectric Coolers (TECs) is that the TECs are external to the Transistor Outline (TO) can package and, as such, require a substantial amount of space. One way to address this issue is to integrate the TEC within the TO can package. FIG. 5 illustrates a TO can package 44 having an integrated TEC 46. Here, the TEC 46 is a conventional, stand-alone TEC 46. The TO can package 44 includes a TO header 48. During manufacturing, the TEC 46 is attached to the surface of the TO header 48, e.g., using solder or thermally conductive epoxy. A laser diode assembly 50 is attached to the surface of the TEC 46 opposite the TO header 48, either before or after the TEC 46 is attached to the TO header 48. While not illustrated, the TO can package 44 also includes a TO cap.

One issue with the TO can package 44 of FIG. 5 is that, since the TEC 46 is a conventional, stand-alone TEC, a bottom header 52 of the TEC 46 has a thickness (t) that is relatively large in order to provide structural support for the stand-alone TEC 46. The thickness (t) of the bottom header 52 is greater than 100 micrometers (pm). The thickness (t) of the bottom header 52 becomes an issue because, in many implementations, there are strict requirements on a total thickness of the TO can package 44 and, in particular, on the total thickness of the TO header 48 plus the TO cap (not illustrated). The strict requirements on the total thickness and the relatively large thickness (t) of the bottom header 52 of the stand-alone TEC 46 restrict the thickness of N-type and P-type legs 54 and 56 of the stand-alone TEC 46 and, thus, a heat pumping capacity of the stand-alone TEC 46. Therefore, there is a need for a TO can package having an integrated TEC having improved heat pumping capacity without substantially increasing the total height of the TO can package.

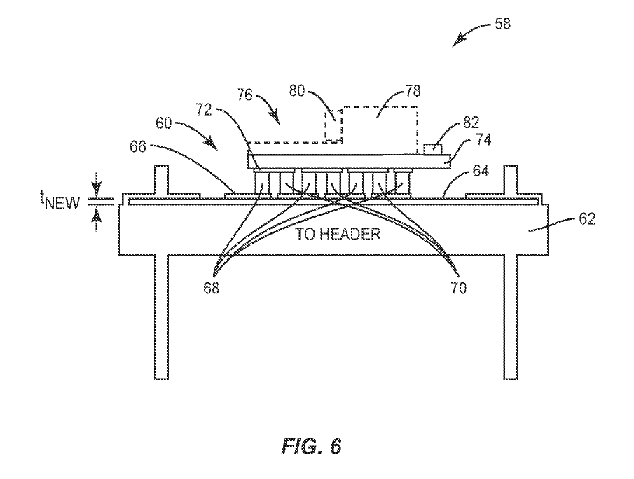

In this regard, FIG. 6 illustrates one example of a TO can package 58 including an integrated TEC 60 that addresses the issues discussed above. As illustrated, the TO can package 58 includes a TO header 62, which may also be referred to herein as a “TO can header.” Rather than attaching a stand-alone TEC onto the surface of the TO header 62, the TEC 60 is formed on the surface of the TO header 62. Specifically, a bottom header 64 of the TEC 60 is formed on the surface of the TO header 62. The bottom header 64 is also referred to herein as an insulation layer 64. This enables a thickness (t_{NEW}) of the bottom header 64 of the TEC 60 to be less than 100 μm and, in some embodiments, substantially less than 100 μm. Thus, in some embodiments, the thickness (t_{NEW}) of the bottom header 64 of the TEC 60 is less than 100 μm. In other embodiments, the thickness (t_{NEW}) of the bottom header 64 of the TEC 60 is less than 75 μm, less than 50 μm, less than 25 μm, less than 10 μm, or less than 5 μm. The bottom header 64 is formed of one or more electrically insulating, thermally conductive materials. For example, in some embodiments, the bottom header 64 is formed of SiO₂, SiN, AlN, or AlO.

The TEC 60 also includes a bottom metallization layer 66 formed on the surface of the bottom header 64 opposite the TO header 62. The bottom metallization layer 66 is patterned to provide the desired metal interconnects for the TEC 60, as will be appreciated by one of skill in the art. In this example, the TEC 60 also includes multiple alternating N-type and P-type legs 68 and 70 and a top metallization layer 72 that, together with the bottom metallization layer 66, form a number of series-connected thermoelectric devices. The TEC 60 also includes a top header 74 formed of one or more electrically insulating, thermally conductive materials. For example, in some embodiments, the top header 74 is formed of SiO₂, SiN, AlN, or AlO.

It should be noted that, in this example, the TEC 60 includes a single layer of series-connected thermometric devices. In other words, the bottom metallization layer 66, the N-type and P-type legs 68 and 70, and the top metallization layer 72 form multiple series-connected thermoelectric devices. However, the present disclosure is not limited to a single layer of series-connected thermoelectric devices. In some other embodiments, the TEC 60 includes multiple layers of thermoelectric devices, where the layers are separated by intermediate headers. The multiple layers of thermoelectric devices form a cascaded arrangement that, e.g., provides a higher ΔT (temperature differential) between the top and bottom surfaces of the TEC 60, as will be appreciated by one of skill in the art.

The thin bottom header 64 enables taller N-type and P-type legs 68 and 70 within a given height for the TEC 60. This results in a higher Coefficient of Performance (COP). The thin bottom header 64 also leads to lower COP losses due to a lower thermal resistance, as compared to that of a bottom header having a thickness greater than 100 μm. Still further, the integrated TEC 60 results is a simplified Bill of Materials (BOM) for the TO can package 58 and fewer manufacturing process steps.

In some embodiments, the TO can package 58 also includes a laser diode assembly 76 attached to a surface of the TEC 60 opposite the TO header 62. In this example, the laser diode assembly 76 includes a heat sink 78 formed of a metal or high thermal conductivity material and a laser diode 80 attached to the heat sink 78. Optionally, additional semiconductor devices may be formed on or attached to the top header 74 of the TEC 60. For example, a thermistor 82 may be attached to the top header 74.

Note that the laser diode assembly 76 is only an example. Other types of semiconductor device assemblies may additionally or alternatively be used. In other words, while in this example, the TO can package 58 is a laser diode TO can package, the present disclosure is not limited thereto. The TO can package 58 may be used for any type of semiconductor device for which cooling is desired or needed.

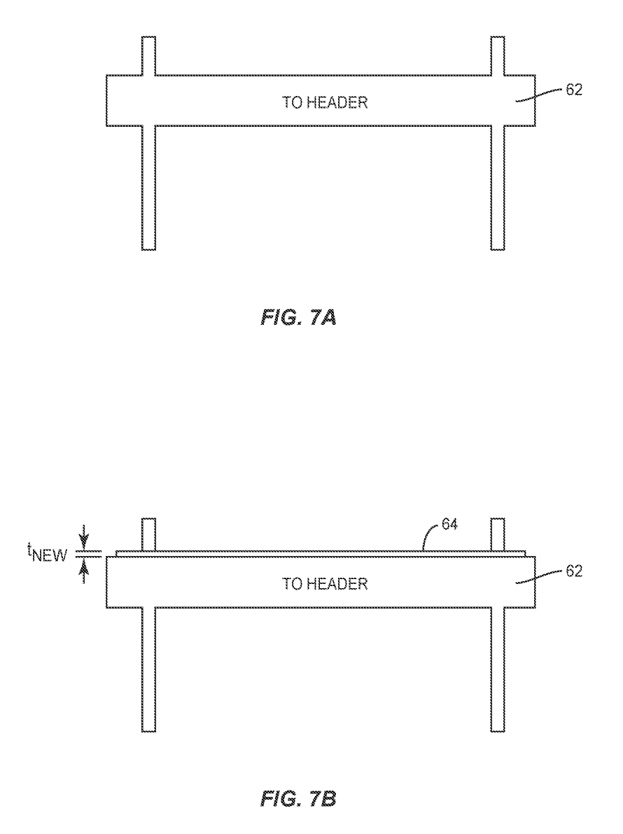

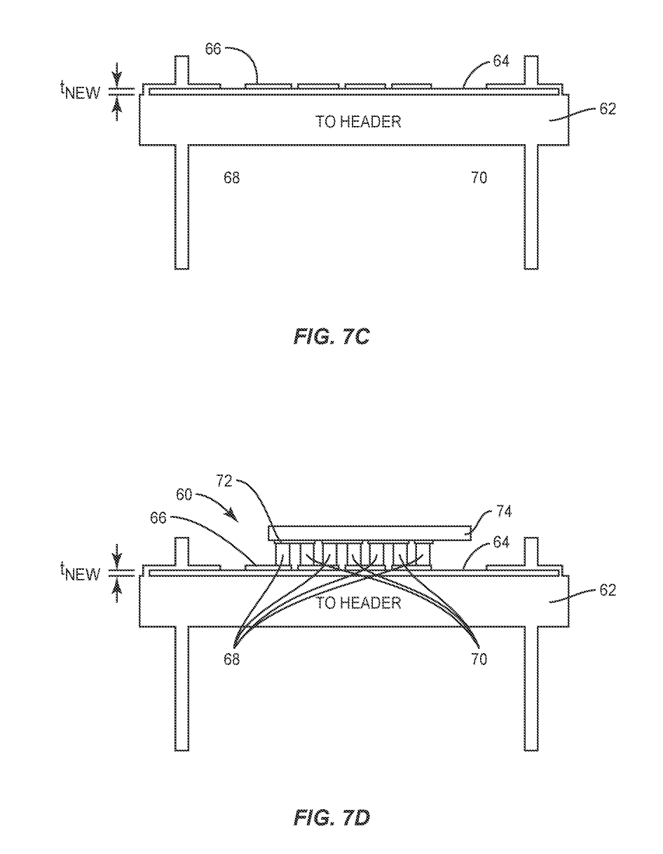

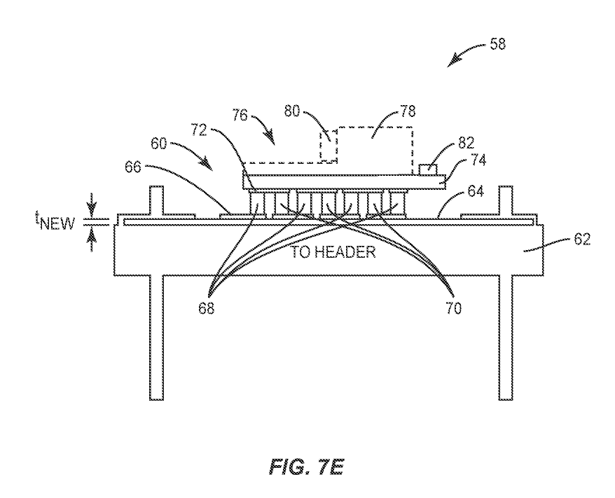

FIGS. 7A through 7E illustrate one example process for manufacturing the TO can package 58 of FIG. 6. As illustrated in FIG. 7A, the process begins with the TO header 62. Next, as illustrated in FIG. 7B, the bottom header 64 of the TEC 60 is formed on the surface of the TO header 62. For example, in some embodiments, the bottom header 64 is formed by depositing one or more electrically insulating, thermally conductive materials (e.g., SiO₂, SiN, AlN, or AIO) on the surface of the TO header 62. As discussed above, the bottom header 64 is formed such that the thickness (t_{NEW}) of the bottom header 64 is less than 100 μm, less than 75 μm, less than 50 μm, less than 25 μm, less than 10 μm, or less than 5 μm depending on the particular embodiment.

As illustrated in FIG. 7C, the bottom metallization layer 66 is formed on the surface of the bottom header 64 opposite the TO header 62. More specifically, as an example, one or more metal layers are deposited or otherwise formed on the surface of the bottom header 64 opposite the TO header 62 and then patterned to form the bottom metallization layer 66 for the TEC 60. However, this is only an example; other patterning techniques may be used.

In this example, the top header 74, the top metallization layer 72, and the N-type and P-type legs 68 and 70 are formed separately. The ends of the N-type and P-type legs 68 and 70 opposite the top metallization layer 72 are aligned with the bottom metallization layer 66 and attached, e.g., by solder, as illustrated in FIG. 7D. In this manner, the TEC 60 is formed on the surface of the TO header 62. As one example alternative, the TEC 60 N-type and P-type legs 68 and 70, the top metallization layer 72, and the top header 74 may be formed on the bottom metallization layer 66.

As illustrated in FIG. 7E, in some embodiments, the laser diode assembly 76 is attached to the surface of the TEC 60 opposite the TO header 62, e.g., via a thermal paste. As noted above, the laser diode assembly 76 is only an example. The TO can package 58 with the integrated TEC 60 may be used for other types of electronic devices.

Those skilled in the art will recognize improvements and modifications to the preferred embodiments of the present disclosure. All such improvements and modifications are considered within the scope of the concepts disclosed herein and the claims that follow.

1. A Transistor Outline (TO) can package, comprising:
a TO header; and
a Thermoelectric Cooler (TEC) on a surface of the TO header, the TEC comprising:
an insulation layer on a surface of the TO header, the insulation layer having a thickness that is a non-zero value that is less than 100 micrometers and comprising one or more thermally and electrically conductive materials; and
a plurality of thermoelectric devices on a surface of the insulation layer opposite the TO header.

2. The TO can package of claim 1 wherein the thickness of the insulation layer is less than 75 micrometers.

3. The TO can package of claim 1 wherein the thickness of the insulation layer is less than 50 micrometers.

4. The TO can package of claim 1 wherein the thickness of the insulation layer is less than 25 micrometers.

5. The TO can package of claim 1 wherein the thickness of the insulation layer is less than 10 micrometers.

6. The TO can package of claim 1 wherein the thickness of the insulation layer is less than 5 micrometers.

7. The TO can package of claim 1 wherein the plurality of thermoelectric devices are arranged into a single layer of thermoelectric devices.

8. The TO can package of claim 1 wherein the plurality of thermoelectric devices are arranged into multiple cascaded layers of thermoelectric devices.

9. The TO can package of claim 1 further comprising a semiconductor device assembly on a surface of the TEC opposite the TO header.

10. The TO can package of claim 9 wherein the semiconductor device assembly comprises a laser diode assembly.

11. A method of manufacturing a Transistor Outline (TO) can package, comprising:
forming a Thermoelectric Cooler (TEC) on a surface of a TO header of the TO can package, the TEC comprising:
an insulation layer on a surface of the TO header, the insulation layer having a thickness that is a non-zero value that is less than 100 micrometers and comprising one or more thermally and electrically conductive materials; and
a plurality of thermoelectric devices on a surface of the insulation layer opposite the TO header.

12. The method of claim 11 wherein the thickness of the insulation layer is less than 75 micrometers.

13. The method of claim 11 wherein the thickness of the insulation layer is less than 50 micrometers.

14. The method of claim 11 wherein the thickness of the insulation layer is less than 25 micrometers.

15. The method of claim 11 wherein the thickness of the insulation layer is less than 10 micrometers.

16. The method of claim 11 wherein the thickness of the insulation layer is less than 5 micrometers.

17. The method of claim 11 wherein forming the TEC comprises forming the insulation layer on the surface of the TO header.

18. The method of claim 17 wherein forming the insulation layer comprises depositing the insulation layer on the surface of the TO header.

19. The method of claim 17 wherein forming the TEC further comprises:
forming a first metallization layer of the TEC on the surface of the insulation layer opposite the TO header

20. The method of claim 19 wherein forming the TEC further comprises:
attaching a structure to the first metallization layer to thereby form the TEC, the structure comprising a plurality of thermoelectric device legs and a second metallization layer;
wherein attaching the structure to the first metallization layer comprises attaching the plurality of thermoelectric device legs to the first metallization layer such that, together, the first metallization layer, the plurality of thermoelectric device legs, and the second metallization layer form a plurality of series-connected thermoelectric devices.

21. The method of claim 11 wherein the plurality of thermoelectric devices are arranged into a single layer of thermoelectric devices.

22. The method of claim 11 wherein the plurality of thermoelectric devices are arranged into multiple cascaded layers of thermoelectric devices.

23. The method of claim 11 further comprising attaching a semiconductor device assembly to a surface of the TEC opposite the TO header.

24. The method of claim 23 wherein the semiconductor device assembly comprises a laser diode assembly.
